(19) United States
(12) Patent Application Publication
(10) Pub. No.: US 2023/0246114 A1
(43) Pub. Date: Aug. 3, 2023

(54) ELECTRODE COUPLED DOUBLE HETEROJUNCTION SOLAR CELL HAVING DOUBLE ACTIVE REGIONS FOR PHOTOELECTRIC EFFECT AND METHOD OF MANUFACTURING THE SAME

(71) Applicant: INNOVATION & INFINITY LTD., Hsinchu City (TW)

(72) Inventor: CHAO-CHIEH CHU, Hsinchu City (TW)

(21) Appl. No.: 17/853,075

(22) Filed: Jun. 29, 2022

(30) Foreign Application Priority Data
Jan. 28, 2022 (TW) 111103809

(51) Int. Cl. H01L 31/05; H01L 31/0224; H01L 31/0216

(52) U.S. Cl. CPC H01L 31/0504; H01L 31/022425; H01L 31/02168; H01L 31/02366

(57) ABSTRACT

An electrode coupled double heterojunction solar cell having double active regions for photoelectric effect and method of manufacturing the same are provided. The electrode coupled double heterojunction solar cell includes a first terminal electrode, a first solar cell, a second solar cell, a common electrode structure, and a second terminal electrode. The first solar cell is connected to the first terminal electrode and includes a first PIN heterojunction structure. The second solar cell is disposed on the first solar cell and includes a second PIN heterojunction structure. The common electrode structure is disposed between the first solar cell and the second solar cell, so that the first solar cell and the second solar cell are electrically connected to each other in a parallel manner. The second terminal electrode is disposed on the second solar cell.

### CROSS-REFERENCE TO RELATED PATENT APPLICATION

This application claims the benefit of priority to Taiwan Patent Application No. 111103809, filed on Jan. 28, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a double heterojunction solar cell and a method of manufacturing the same, and more particularly to an electrode coupled double heterojunction solar cell having double active regions for photoelectric effect to improve a conversion efficiency and a method of manufacturing method the same.

### BACKGROUND OF THE DISCLOSURE

A solar cell can absorb sunlight and convert optical energy to electric energy. Currently, most solar cells on the market are silicon based solar cells, which is made of single crystalline silicon, polycrystalline silicon, or amorphous silicon. Reference is made to FIG. 1. A conventional silicon-based solar cell 1 includes a P-type substrate 10, a N-type doped layer 11, an anti-reflective layer 12, a front electrode 13, a back passivation layer 14, and a back electrode 15.

The N-type doped layer 11 is formed at one side of the P-type substrate 10 and has a textured surface. The anti-reflective layer 12 is formed on the textured surface of the N-type doped layer 11, and the front electrode 13 passes through the anti-reflective layer 12 to form an ohmic contact with the N-type doped layer 11. Furthermore, the back passivation layer 14 is formed at a bottom surface of the P-type substrate 10 so as to reduce a recombination rate, and the back passivation layer 14 is usually a silicon oxide layer or a silicon nitride layer. The back passivation layer 14 has a local opening, and the back electrode 15 is electrically connected to the P-type substrate 11 through the local opening. However, a photoelectric conversion efficiency of the conventional silicon-based solar cell is about 21% to 22%, and at most up to 25%. Accordingly, how the photoelectric conversion efficiency of the solar cell can be improved is still one of issues to be addressed in the industry.

### SUMMARY OF THE DISCLOSURE

In response to the above-referenced technical inadequacies, the present disclosure provides an electrode coupled double heterojunction solar cell having double active regions for photoelectric effect and a method of manufacturing the same are provided, so as to improve a photoelectric conversion efficiency.

In one aspect, the present disclosure provides a method of manufacturing an electrode coupled double heterojunction solar cell having double active regions for photoelectric effect. The method includes the following steps: forming a first solar cell on a first terminal electrode, in which the first solar cell includes a first PIN heterojunction structure; forming a common electrode structure on the first solar cell; forming a second solar cell on the common electrode structure, in which the second solar cell includes a second PIN heterojunction structure, and the second solar cell is electrically connected to the first solar cell in a parallel manner through the common electrode structure; and forming a second terminal electrode on the second solar cell.

In another aspect, the present disclosure provides an electrode coupled double heterojunction solar cell having double active regions for photoelectric effect including a first terminal electrode, a first solar cell, a second solar cell, a common electrode structure, and a second terminal electrode. The first solar cell is connected to the first terminal electrode, and the first solar cell includes a first PIN heterojunction structure. The second solar cell is disposed on the first solar cell, and the second solar cell includes a second PIN heterojunction structure. The common electrode structure is disposed between the first solar cell and the second solar cell, so that the first solar cell and the second solar cell are electrically connected to each other in a parallel manner. The second terminal electrode is disposed on the second solar cell.

Therefore, in the electrode coupled double heterojunction solar cell having double active regions for photoelectric effect and the method of manufacturing the same provided by the present disclosure, by virtue of the common electrode structure being disposed between the first solar cell and the second solar cell so that the first solar cell and the second solar cell are electrically connected to each other in a parallel manner, a photoelectric conversion efficiency of the electrode coupled double heterojunction solar cell having double active regions for photoelectric effect can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a conventional silicon-based solar cell.

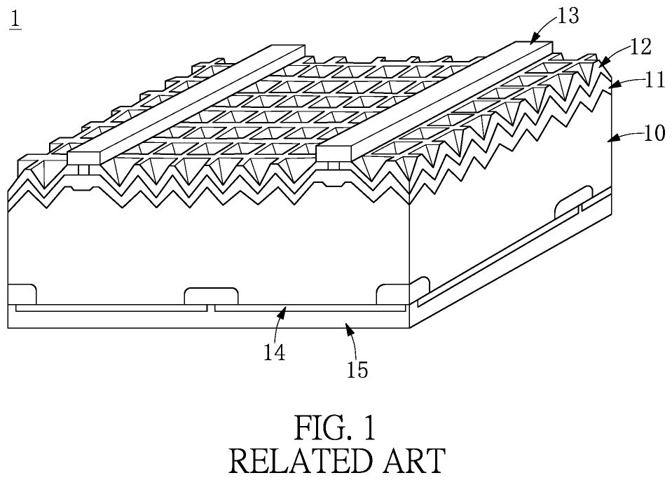

FIG. 2 is a schematic view of an electrode coupled double heterojunction solar cell having double active regions for photoelectric effect according to a first embodiment of the present disclosure;

FIG. 3 is a part of a schematic perspective view of an electrode coupled double heterojunction solar cell having double active regions for photoelectric effect according to one embodiment of the present disclosure;

FIG. 4 is a schematic top view of an electrode coupled double heterojunction solar cell having double active regions for photoelectric effect according to one embodiment of the present disclosure;

FIG. 5 is a flowchart of a method of manufacturing an electrode coupled double heterojunction solar cell having double active regions for photoelectric effect according to one embodiment of the present disclosure;

FIG. 6 is a schematic view showing a step of forming a first terminal electrode in the method according to one embodiment of the present disclosure;

FIG. 7 is a schematic view showing a step of forming a first solar cell in the method according to one embodiment of the present disclosure;

FIG. 8 is a schematic view after a step of forming an anti-reflective film in the method according to one embodiment of the present disclosure;

FIG. 9 is a schematic top view of a sputtering deposition system according to one embodiment of the present disclosure;

FIG. 10 is a schematic view after a step of forming a common conductive patterned layer according to one embodiment of the present disclosure;

FIG. 11 is a schematic top view of the common conductive patterned layer according to one embodiment of the present disclosure;

FIG. 12 is a schematic view after a step of forming a patterned insulating layer according to one embodiment of the present disclosure;

FIG. 13 is a schematic view after a step of forming the second solar cell and the anti-reflective layer according to one embodiment of the present disclosure;

FIG. 14 is a schematic view showing a step of forming a second terminal electrode in the method according to one embodiment of the present disclosure;

FIG. 15 is a schematic view of an electrode coupled double heterojunction solar cell having double active regions for photoelectric effect according to a second embodiment of the present disclosure; and

FIG. 16 shows optical spectral responses of the first solar cell and the second solar cell of the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

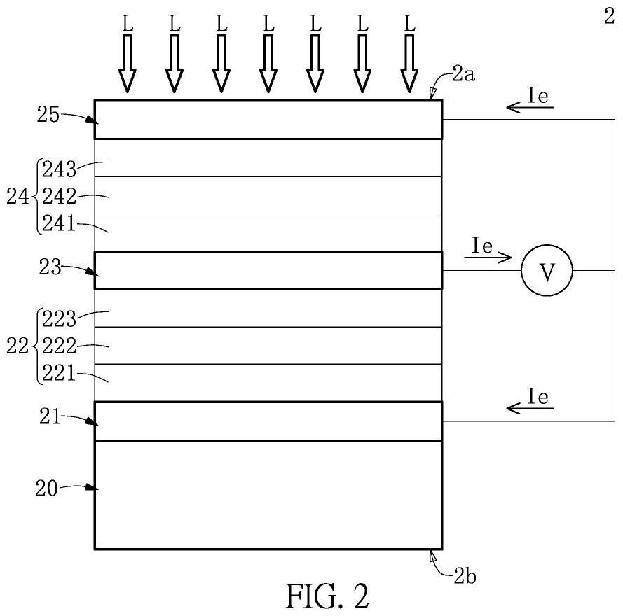

Referring to FIG. 2, an electrode coupled double heterojunction solar cell having double active regions for photoelectric effect 2 (hereinafter referred to as “double heterojunction solar cell 2”) is provided in the first embodiment of the present disclosure, and includes a first terminal electrode 21, a first solar cell 22, a common electrode structure 23, a second solar cell 24, and a second terminal electrode 25.

The double heterojunction solar cell 2 has a light receiving side 2a and a back side 2b that is opposite to the light receiving side 2a. In the instant embodiment, sunlight L enters the double heterojunction solar cell 2 from the light receiving side 2a, so that a photocurrent is generated in the double heterojunction solar cell 2.

In the instant embodiment, the first terminal electrode 21 is closer to the back side 2b and farther away from the light receiving side 2a. Specifically, the double heterojunction solar cell 2 further includes a substrate 20, and the first terminal electrode 21 is disposed on the substrate 20.

In the instant embodiment, the substrate 20 can be made of transparent or opaque material, for example, glass or silicon (or Si wafer), but the present disclosure is not limited thereto. Furthermore, the first terminal electrode 21 can be made of silver, but the present disclosure is not limited thereto. In the instant embodiment, since the first terminal electrode 21 is closer to the back side 2b and farther away from the light receiving side 2a, and sunlight L enters the double heterojunction solar cell 2 without passing through the back side 2b, the first terminal electrode 21 can have a relatively larger thickness to improve its conductivity. In one embodiment, the thickness of the first terminal electrode 21 can range from 500 nm to 1000 nm.

As shown in FIG. 2, the first solar cell 22 is disposed on the first terminal electrode 21 and has a first PIN heterojunction structure. Specifically, the first solar cell 22 includes a first P-type semiconductor layer 221, a first intrinsic semiconductor layer 222, and a first N-type semiconductor layer 223, so as to form the aforementioned first PIN heterojunction structure.

In the instant embodiment, the first P-type semiconductor layer 221, a first intrinsic semiconductor layer 222, and the first N-type semiconductor layer 223 are sequentially stacked on the first terminal electrode 21. That is to say, the first P-type semiconductor layer 221 is connected to the first terminal electrode 21, and the first intrinsic semiconductor layer 222 is disposed between the first P-type semiconductor layer 221 and the first N-type semiconductor layer 223.

In one embodiment, each one of the first N-type semiconductor layer 223, the first intrinsic semiconductor layer 222, and the first P-type semiconductor layer 221 has a thickness ranging from 2 nm to 80 nm. For example, each of the thicknesses of the first P-type semiconductor layer 221 and the first N-type semiconductor layer 222 is 50 nm, and the thickness of the first intrinsic semiconductor layer 222 ranges from 20 nm to 80 nm. In one preferred embodiment, the thickness of each of the first P-type semiconductor layer 221, the first intrinsic semiconductor layer 222, and the first N-type semiconductor layer 223 is 50 nm, but the present disclosure is not limited thereto.

In the instant embodiment, the first P-type semiconductor layer 221 and the first N-type semiconductor layer 223 are heavily doped semiconductor layer, and each have a relatively lower sheet resistivity. In one preferred embodiment, the sheet resistivity of each of the first P-type semiconductor layer 221 and the first N-type semiconductor layer 223 is less than 10⁻² ohm-square, preferably, less than or equal to 0.005 ohm-square. Accordingly, an internal resistance of the double heterojunction solar cell 2 can be reduced, which improves a photoelectric conversion efficiency.

Furthermore, the second solar cell 24 is closer to the light receiving side 2a and includes a second PIN heterojunction structure. Specifically, the second solar cell 24 includes a second N-type semiconductor layer 241, a second intrinsic semiconductor layer 242, and a second P-type semiconductor layer 243, so as to form the aforementioned second PIN heterojunction structure. In the instant embodiment, the second N-type semiconductor layer 241, the second intrinsic semiconductor layer 242, and the second P-type semiconductor layer 243 are sequentially stacked on the common electrode structure 23.

In one embodiment, each one of the second N-type semiconductor layer 241, the second intrinsic semiconductor layer 242, and the second P-type semiconductor layer 243 has a thickness ranging from 2 nm to 80 nm. For example, each of the thicknesses of the second P-type semiconductor layer 243 and the second N-type semiconductor layer 241 is 50 nm, and the thickness of the second intrinsic semiconductor layer 242 is about 20 nm. In another embodiment, the thickness of each of the second P-type semiconductor layer 243 and the second N-type semiconductor layer 241 is 50 nm, and the thickness of the second intrinsic semiconductor 242 is 80 nm, but the present disclosure is not limited thereto.

In the instant embodiment, the second P-type semiconductor layer 243 and the second N-type semiconductor layer 241 are both heavily doped semiconductor layers, and each have a relatively lower sheet resistivity. In one exemplary embodiment, the sheet resistivity of each of the second P-type semiconductor layer 243 and the second N-type semiconductor layer 241 is less than 10⁻² ohm-square, and preferably, less than or equal to 0.005 ohm-square. Accordingly, an internal resistance of the double heterojunction solar cell 2 can be reduced, which improves a photoelectric conversion efficiency.

It should be noted that compared to light having a higher optical energy (or a shorter wavelength), a penetration depth of light having a lower optical energy (or a wavelength greater than 700 nm) in silicon material is larger. In the instant embodiment, since the first solar cell 22 is farther away from the light receiving side 2a, the first solar cell 22 can be configured to absorb light contained in sunlight L and having a lower optical energy (or a longer wavelength). Furthermore, the second solar cell 24 is closer to the light receiving side 2a, and can be configured to absorb light contained in sunlight L and having a higher optical energy (or a shorter wavelength).

In one embodiment, the first solar cell 22 can be made of polycrystalline silicon or micro-crystalline silicon, so as to absorb the light having a lower optical energy. Specifically, the first P-type semiconductor layer 221, the first intrinsic semiconductor layer 222, and the first N-type semiconductor layer 223 can be made of polycrystalline silicon or microcrystalline silicon. Furthermore, an average grain size of each of the first P-type semiconductor layer 221, the first intrinsic semiconductor layer 222, and the first N-type semiconductor layer 223 can range from 5 nm to 80 nm, or preferably, from 20 nm to 80 nm.

Furthermore, the second solar cell 24 can be mainly made of amorphous silicon so as to absorb the light having a higher optical energy. As such, the photoelectric conversion efficiency of the double heterojunction solar cell 2 can be improved. Specifically, the second intrinsic semiconductor layer 242 and the second P-type semiconductor layer 243 are both made of amorphous silicon. However, the second N-type semiconductor layer 241 can be made of amorphous silicon, microcrystalline silicon, or polycrystalline silicon. In this way, after sunlight L enters the double heterojunction solar cell 2 from the light receiving side 2a, the light having a higher optical energy can be absorbed by the second solar cell 24.

As shown in FIG. 2, the common electrode structure 23 is disposed between the first solar cell 22 and the second solar cell 24 so that the first solar cell 22 and the second solar cell 24 can be electrically connected to each other in a parallel manner. Specifically, the common electrode structure 23 is electrically connected to the first N-type semiconductor layer 223 of the first solar cell 22 and electrically connected to the second N-type semiconductor layer 241 of the second solar cell 24.

Referring to FIG. 2, the second terminal electrode 25 is disposed on the second solar cell 24. Moreover, the second P-type semiconductor layer 243 of the second solar cell 24 is electrically connected to the second terminal electrode 25.

As shown in FIG. 2, after the sunlight L enters the double heterojunction solar cell 2 form the light receiving side 2a and are absorbed by the first solar cell 22 and the second solar cell 24, photoelectron currents Ie generated in the first solar cell 22 and the second solar cell 24 flow together to the common electrode structure 23 and are then drawn out from the common electrode structure 23.

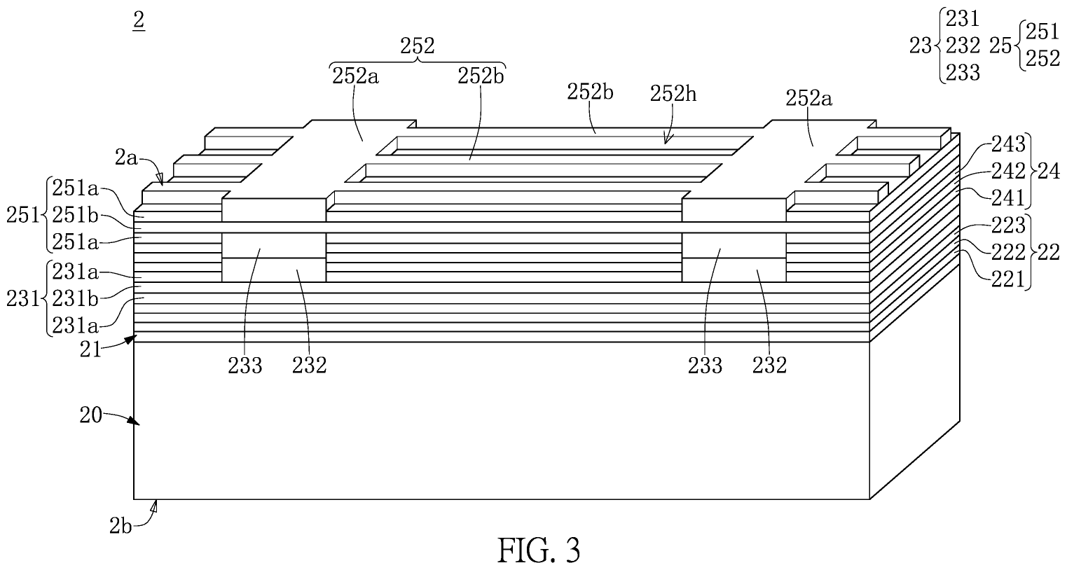

The detailed structure of the double heterojunction solar cell 2 of the embodiment of the present disclosure will be further described in the following contents. As shown in FIG. 3, the common electrode structure 23 of the double heterojunction solar cell 2 can further include an internal anti-reflective layer 231, a common conductive patterned layer 232, and a patterned insulating layer 233.

It is worth mentioning that since the common electrode structure 23 is disposed between the first solar cell 22 and the second solar cell 24, the internal anti-reflective layer 231 is embedded in the double heterojunction solar cell 2, instead of exposed at the light receiving side 2a. The internal anti-reflective layer 231 is an optical film having a lower refractive index and allows the light having a longer wavelength to pass therethrough. Specifically, the internal anti-reflective layer 231 of the instant embodiment includes one or more transparent oxide layers 231a (two of which are exemplified in FIG. 3) and a metal layer 231b.

It should be noted that by selecting materials, thicknesses, and layer numbers of the transparent oxide layers 231a and the metal layer 231b, an optical property of the internal anti-reflective layer 231 can be adjusted, so that the internal anti-reflective layer 231 has a higher transmittance for the light to be absorbed by the first solar cell 22. Furthermore, a resistivity of the internal anti-reflective layer 231 should not be too high, so that the internal resistance of the double heterojunction solar cell 2 can be reduced as much as possible.

In the embodiment shown in FIG. 3, the metal layer 231b is interposed between two transparent conductive oxide layers 231a. Furthermore, the material of the transparent conductive oxide layer 231a is, for example, indium tin oxide (ITO), and the material of the metal layer 231b is, for example, silver. Moreover, each of the transparent conductive oxide layers 231a has the thickness ranging from 30 nm to 70 nm, preferably 50 nm. The thickness of the metal layer 231b can range from 2 nm to 8 nm, preferably 4 nm. However, the present disclosure is not limited to the examples provided herein.

Reference is made to FIG. 3. The common conductive patterned layer 232 is disposed on the internal anti-reflective layer 231. In one embodiment, from a top view, the common conductive patterned layer 232 is in a mesh shape and has a plurality of openings, so as to avoid excessive decrease of a light receiving area of the first solar cell 22. In one embodiment, the common conductive patterned layer 232 is made of copper, but the present disclosure is not limited thereto. The detailed structure and shape of the common conductive patterned layer 232 will be explained in the following description and thus is not reiterated herein.

In the instant embodiment, the common electrode structure 23 further includes the patterned insulating layer 233. The patterned insulating layer 233 covers the common conductive patterned layer 232, so that the common conductive patterned layer 232 is electrically isolated from the second P-type semiconductor layer 243 to avoid short circuits. In one embodiment, from the top view, the patterned insulating layer 233 has the same shape as that of the common conductive patterned layer 232, that is, the patterned insulating layer 233 is in a mesh shape. Furthermore, the patterned insulating layer 233 has a thickness ranging from 150 nm to 250 nm, and preferably, from 180 nm to 220 nm, but the present disclosure is not limited thereto. The patterned insulating layer 233 can be made of, for example, silicon oxide, but it is not limited thereto.

The second terminal electrode 25 includes a surface anti-reflective layer 251 and a conductive patterned layer 252. Since the surface anti-reflective layer 251 is near the light receiving side 2a, the surface anti-reflective layer 251 is an optical film having a lower refractive index and allowing sunlight L to pass therethrough. Specifically, the surface anti-reflective layer 251 also includes one or more transparent conductive oxide layers 251a and a metal layer 251b.

It should be noted that by selecting materials, thicknesses, and layer numbers of the transparent oxide layers 251a and the metal layer 251b, an optical property of the surface anti-reflective layer 251 can be adjusted, so that the surface anti-reflective layer 251 has a higher transmittance for the light to be absorbed by the first solar cell 22 and the second solar cell 24. Furthermore, a resistivity of the surface anti-reflective layer 251 should not be too high, so that the internal resistance of the double heterojunction solar cell 2 can be reduced as much as possible.

In the embodiment shown in FIG. 3, the metal layer 251b is interposed between two transparent conductive oxide layers 251a. Furthermore, the material of the transparent conductive oxide layer 251a is, for example, indium tin oxide (ITO), and the material of the metal layer 251b is, for example, silver. Moreover, each of the transparent conductive oxide layers 251a has the thickness ranging from 30 nm to 80 nm, preferably 50 nm. The thickness of the metal layer 251b can range from 2 nm to 8 nm, preferably 4 nm. However, the present disclosure is not limited to the examples provided herein.

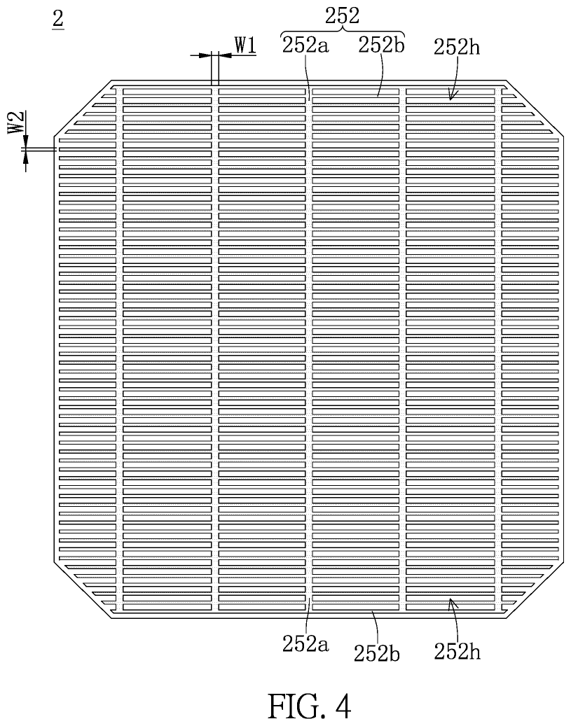

The conductive patterned layer 252 is disposed on the surface anti-reflective layer 251 and electrically connected to the second P-type semiconductor layer 243 of the second solar cell 24. Referring to FIG. 4, FIG. 4 is a schematic top view of the double heterojunction solar cell according to one embodiment of the present disclosure. From the top view, the conductive patterned layer 252 is in a mesh shape and has a plurality of openings 252h to avoid excessive decrease of the light receiving area. In one embodiment, the conductive patterned layer 252 can be made of copper, but it is not limited thereto in the present disclosure.

Specifically, the conductive patterned layer 252 includes a plurality of busbar electrode lines 252a and a plurality of finger electrode lines 252b. Each of the finger electrode lines 252b is connected to a corresponding one of the busbar electrode lines 252a. In the instant embodiment, each of the busbar electrode lines 252a passes through the outermost transparent conductive oxide layer 251a and is connected to the metal layer 251b. Furthermore, each of the busbar electrode lines 252a has a line width W1 ranging from 0.6 mm to 1.4 mm, preferably, from 0.8 mm to 1.2 mm. Each of the finger electrode lines 252b has a line width W2 ranging from 5 μm to 10 μm and has a thickness ranging from 100 nm to 150 nm.

It should be noted that the line widths W1, W2, spacings, and quantities of the busbar electrode lines 252a and the finger electrode lines 252b affects the light receiving area and the internal resistance of the double heterojunction solar cell 2. In one embodiment, the spacing between any two adjacent ones of the finger electrode lines 252b can be from 0.8 mm to 1 mm. Furthermore, the quantity of the busbar electrode lines 252a can be five, and the quantity of the finger electrode lines 252b can be from 155 to 300, but the present disclosure is not limited thereto. The line widths W1, W2, spacings, and quantities of the busbar electrode lines 252a and the finger electrode lines 252b can be adjusted according to practical requirements.

Compared to the conventional silicon-based solar cell 1, the double heterojunction solar cell 2 has a higher photoelectric conversion efficiency. Specifically, the photoelectric conversion efficiency of the double heterojunction solar cell 2 is at least 40%, or even reaches 45%.

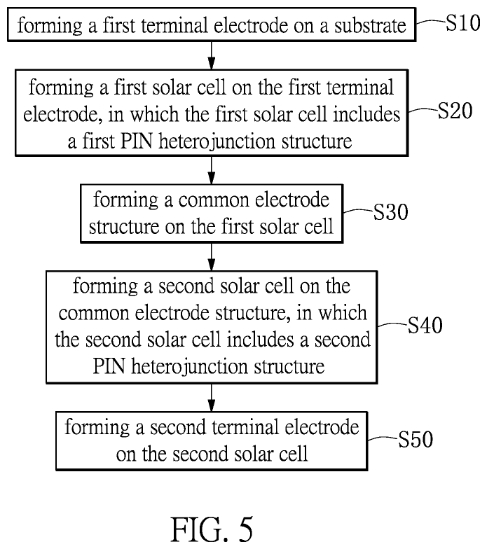

The method of manufacturing the double heterojunction solar cell of the embodiment in the present disclosure will be further described below. Referring to FIG. 5, in step S10, a first terminal electrode is formed on a substrate. In step S20, a first solar cell that has a first PIN heterojunction structure is formed on the first terminal electrode. In step S30, a common electrode structure is formed on the first solar cell. In step S40, a second solar cell that has a second PIN heterojunction structure is formed on the common electrode structure. In step S50, a second terminal electrode is formed on the second solar cell. In the following descriptions, a fabrication of the double heterojunction solar cell shown in FIG. 3 is exemplified for further explaining each of the steps S10˜S50.

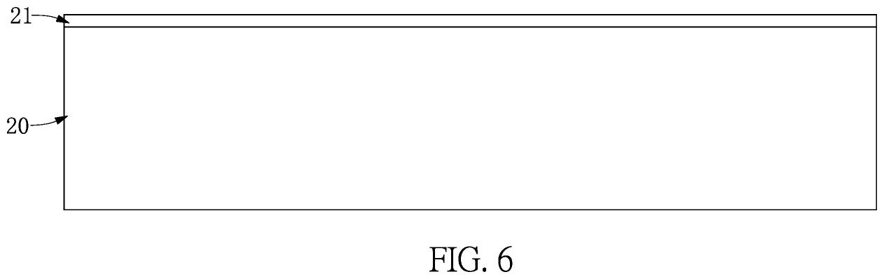

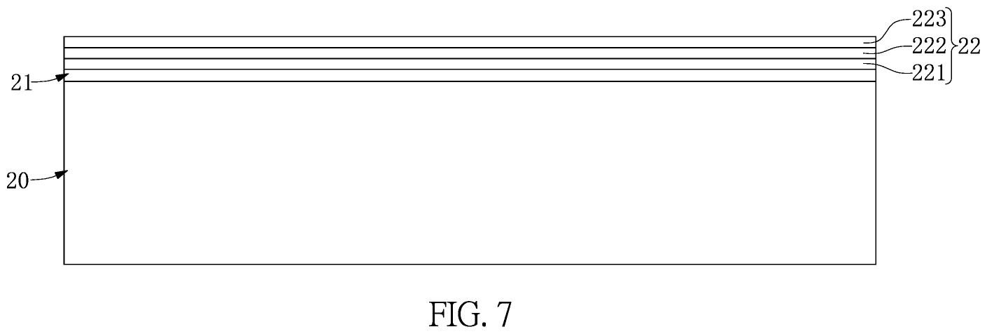

Reference is made to FIG. 6. As mentioned previously, the substrate 20 can be a glass substrate or a silicon substrate and is not limited in the present disclosure. In one embodiment, the first terminal electrode 21 can be formed by a sputtering deposition process. Referring to FIG. 7, the first P-type semiconductor layer 221, the first intrinsic semiconductor layer 222, and the first N-type semiconductor layer 223 of the first solar cell 22 are sequentially formed on the first terminal electrode 21. The first P-type semiconductor layer 221 and the first N-type semiconductor layer 223 are both heavily doped semiconductor layers.

In one embodiment, the P-type semiconductor layer 221, the first intrinsic semiconductor layer 222, and the first N-type semiconductor layer 223 are formed by sputtering deposition processes, such as a DC sputtering deposition process or a RF sputtering deposition process. In one embodiment, by bombarding a heavily doped P-type semiconductor target with a plasma, the aforementioned first P-type semiconductor layer 221 can be formed. Similarly, by bombarding a heavily doped N-type semiconductor target and an intrinsic target with a plasma, the aforementioned first N-type semiconductor layer 223 and the intrinsic semiconductor layer 222 can be formed, respectively. In one embodiment, a resistivity of each of the heavily doped N-type semiconductor target and the heavily doped P-type semiconductor target is about 0.003 ohm-square, so that the first P-type semiconductor layer 221 and the first N-type semiconductor layer 223 each have a lower sheet resistivity.

After the step of forming the first solar cell 22, a rapid thermal annealing process can be performed on the first P-type semiconductor layer 221, the intrinsic semiconductor layer 222, and the first N-type semiconductor layer 223, so that the material of each of the first P-type semiconductor layer 221, the intrinsic semiconductor layer 222, and the first N-type semiconductor layer 223 is converted into microcrystalline silicon or polycrystalline silicon. An average grain size of each of the first P-type semiconductor layer 221, the intrinsic semiconductor layer 222, and the first N-type semiconductor layer 223 can range from 5 nm to 80 nm, preferably, from 20 nm to 80 nm. During the rapid thermal annealing process, the first solar cell 22 together with the substrate 20 are heated to and maintained at a predetermined temperature for a preset time period. The aforementioned predetermined temperature can be set to be in a range from 400° C. to 800° C., and the preset time period can be 2 to 5 minutes.

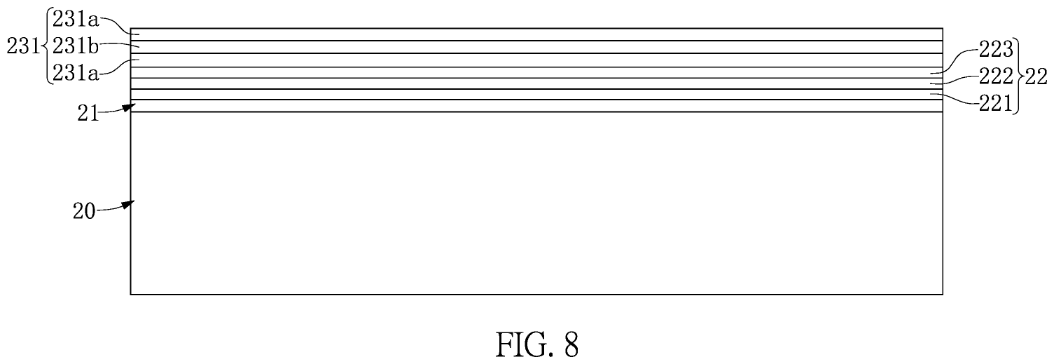

Referring to FIG. 8, the internal anti-reflective layer 231 is formed on the first solar cell 22. As mentioned previously, the internal anti-reflective layer 231 can include two transparent conductive oxide layers 231a and a metal layer 231b interposed therebetween.

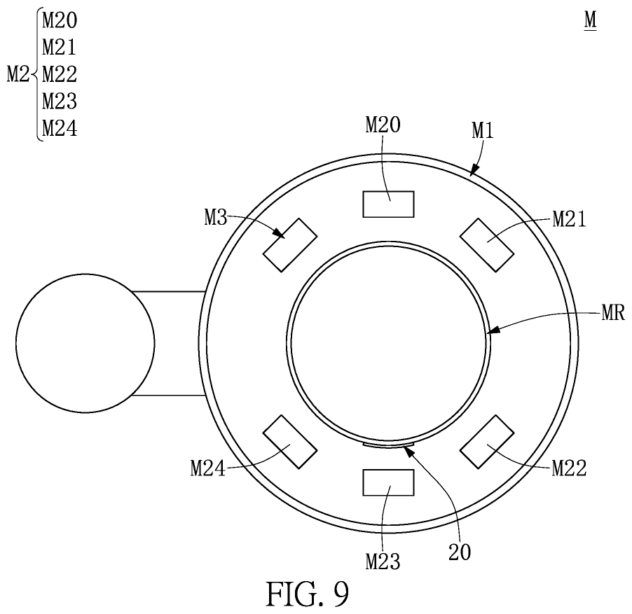

In one embodiment, the internal anti-reflective layer 231 can be formed by sputtering deposition processes. In the instant embodiment, the first terminal electrode 21, the first solar cell 22, and the internal anti-reflective layer 231 can be fabricated in the same deposition chamber. Reference is made to FIG. 9, which is a schematic top view of a sputtering deposition system according to one embodiment of the present disclosure. The sputtering deposition system M includes a deposition chamber M1, a rotatable carrier MR, a target assembly M2, and a heater M3.

As shown in FIG. 9, the substrate 20 can be arranged on the rotatable carrier MR. When the rotatable carrier MR is rotated, the substrate 20 can be rotated around a rotation axis of the rotatable carrier MR to a predetermined position. The target assembly M2 includes a plurality of targets M20-M24 including different target materials, respectively. For example, the target material of the target M20 can be silver, the target material of the target M21 can be heavily doped P-type crystalline silicon, the target material of the target M22 can be intrinsic crystalline silicon, the target material of the target M23 can be heavily doped N-type crystalline silicon, and the target material of the target M24 can be transparent conductive oxide, but the present disclosure is not limited to the examples provided herein. The target materials and a quantity of the targets M20-M24 can be adjusted according to practical requirements.

Accordingly, after the substrate 20 is loaded on the rotatable carrier MR, by the rotating the rotatable carrier MR, the substrate 20 can be transferred to a position corresponding to the target M20 and faces to the target M20, so that the first terminal electrode 21 can be formed on the substrate 20. In one embodiment, by applying a direct-current (DC) voltage or a radiofrequency (RF) voltage, an argon plasma can be generated to bombard the target M20, so that the first terminal electrode 21 can be formed on the substrate 20. Thereafter, the substrate 20 can be rotated and sequentially transferred to positions that respectively correspond to the target M21, the target M22, and the target M23, so that the first P-type semiconductor layer 221, the first intrinsic semiconductor 222, and the first N-type semiconductor layer 223 of the first solar cell 22 can be successively formed. Furthermore, before a thermal treatment is performed on the films that have been formed on the substrate 20, the substrate 20 can be rotated and transferred to a position corresponding to the heater M3. After the fabrication of the first solar cell 22, the substrate 22 can be rotated and transferred to a position corresponding to the target M24, so that the transparent conductive oxide layer 231a can be formed. In one embodiment, during the formation of the transparent conductive oxide layer 231a, an argon-oxygen plasma can be used to bombard the target M24, but the present disclosure is not limited thereto.

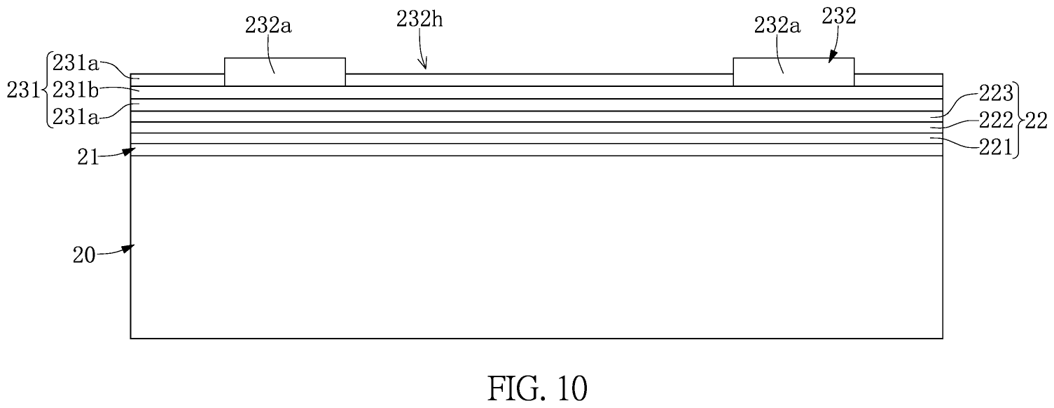

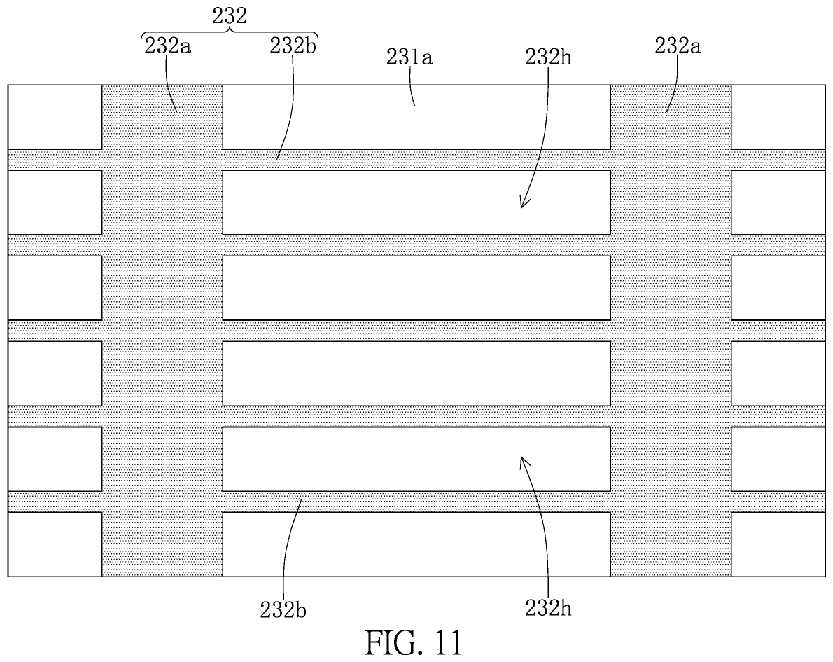

Reference is made to FIG. 10 and FIG. 11. FIG. 10 is a schematic view after a step of forming a common conductive patterned layer according to one embodiment of the present disclosure, and FIG. 11 is a schematic top view of the common conductive patterned layer according to one embodiment of the present disclosure. The common conductive patterned layer 232 is formed on the internal anti-reflective layer 231. As shown in FIG. 11, from the top view, the common conductive patterned layer 232 is in a mesh shape and has a plurality of openings 232h.

Furthermore, the common conductive patterned layer 232 includes a plurality of common busbar electrode lines 232a and a plurality of common finger electrode lines 232b. Each of the common finger electrode lines 232a and each of the common finger electrode lines 232b have different extending directions. Accordingly, the common busbar electrode lines 232a and the common finger electrode lines 232b interlace with each other. In one embodiment, by performing a screen printing process and a sintering process, the aforementioned common conductive patterned layer 232 can be formed.

In the instant embodiment, each of the common busbar electrode lines 232a penetrates through one of the transparent conductive oxide layers 231a and is connected to the metal layer 231b. Furthermore, each of the common busbar electrode lines 232a has a line width ranging from 0.5 mm to 2 mm, preferably from 0.6 mm to 1.4 mm, and more preferably from 0.8 mm to 1.2 mm. Furthermore, each of the finger electrode lines 232b has a line width ranging from 5 μm to 10 μm and has a thickness ranging from 100 nm to 150 nm.

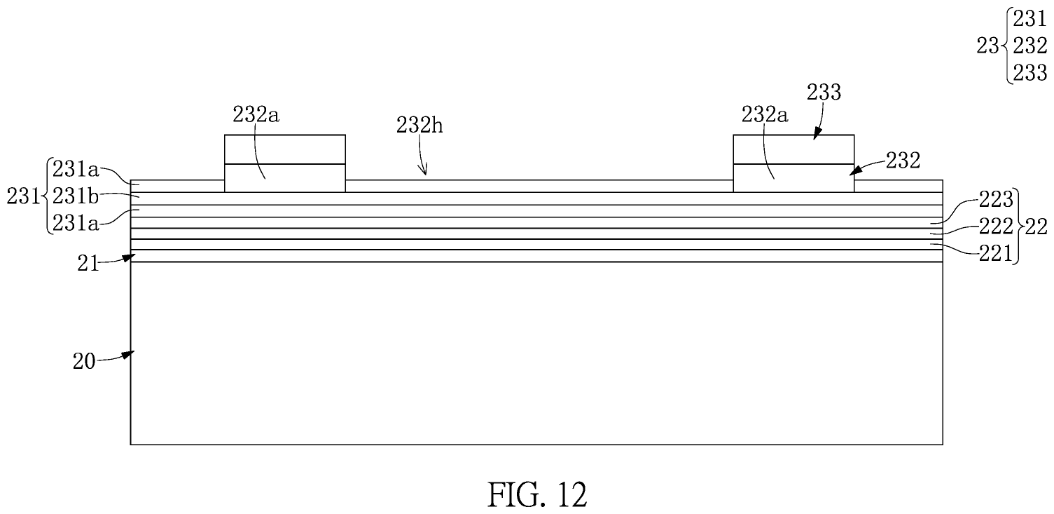

Reference is made to FIG. 12. The patterned insulating layer 233 is formed to cover the common conductive patterned layer 232. The patterned insulating layer 233 can be made of silicon oxide, but it is not limited thereto. Furthermore, from the top view, the patterned insulating layer 233 has the same shape as that of the common conductive patterned layer 232 and is in a mesh shape. In other words, the patterned insulating layer 233 covers the common busbar electrode lines 232a and the common finger electrode lines 232b. In one embodiment, the patterned insulating layer 233 can be formed by performing a screen printing process. In another embodiment, a sputtering deposition process can be performed, and a mask can be utilized during the sputtering deposition process, so that the patterned insulating layer 233 in the mesh shape can be formed.

Reference is made to FIG. 3. The second N-type semiconductor layer 241, the second intrinsic semiconductor layer 242, and the second P-type semiconductor layer 243 can be sequentially formed on the common electrode structure 23 to form the second solar cell 24. The materials and the thicknesses of the second N-type semiconductor layer 241, the second intrinsic semiconductor layer 242, and the second P-type semiconductor layer 243 have been explained in the previous descriptions and are not reiterated herein.

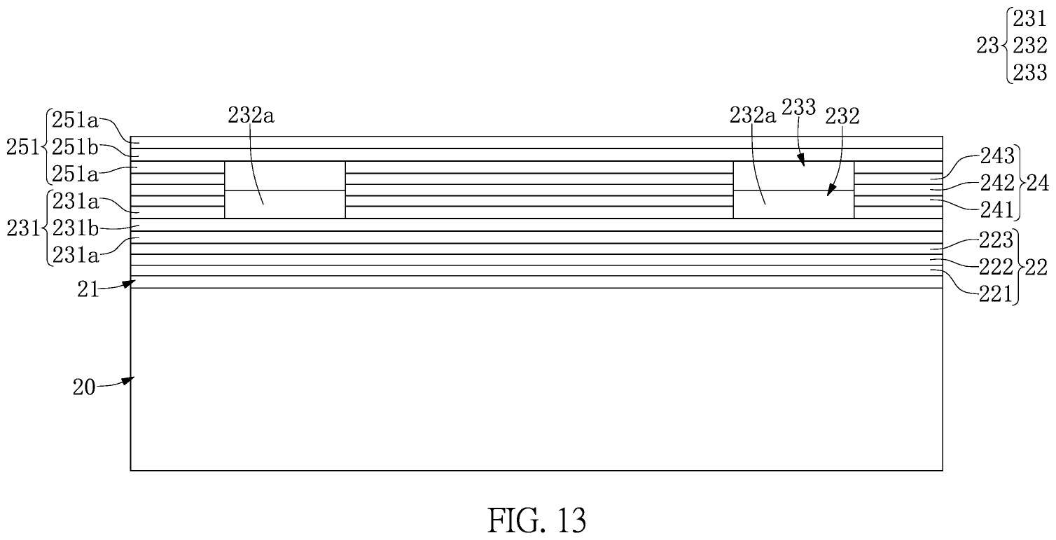

It is worth mentioning that the thickness of the second N-type semiconductor layer 241 of the second solar cell 24 is less than that of each of the common busbar electrode lines 232a. In this way, the second N-type semiconductor layer 241 fills into a gap between two adjacent ones of the common busbar electrode lines 232a and covers the common finger electrode lines 232b. The second N-type semiconductor layer 241 is in contact with the common busbar electrode lines 232a; however, the second N-type semiconductor layer 241 does not completely cover the common busbar electrode lines 232a. Furthermore, as shown in FIG. 13, the second P-type semiconductor layer 243 can be isolated from the common busbar electrode lines 232a by the patterned insulating layer 233.

The surface anti-reflective layer 251 is formed on the second solar cell 24. Specifically, as shown in FIG. 13, one of the transparent conductive oxide layers 251a, the metal layer 251b, and the other transparent conductive oxide layers 251a are sequentially formed on the patterned insulating layer and the second P-type semiconductor layer 243.

It should be noted that in one embodiment, the second solar cell 24 and the surface anti-reflective layer 251 are formed by sputtering deposition processes. Specifically, the sputtering deposition system shown in FIG. 9 can be utilized to fabricate the second solar cell 24 and the surface anti-reflective layer 251.

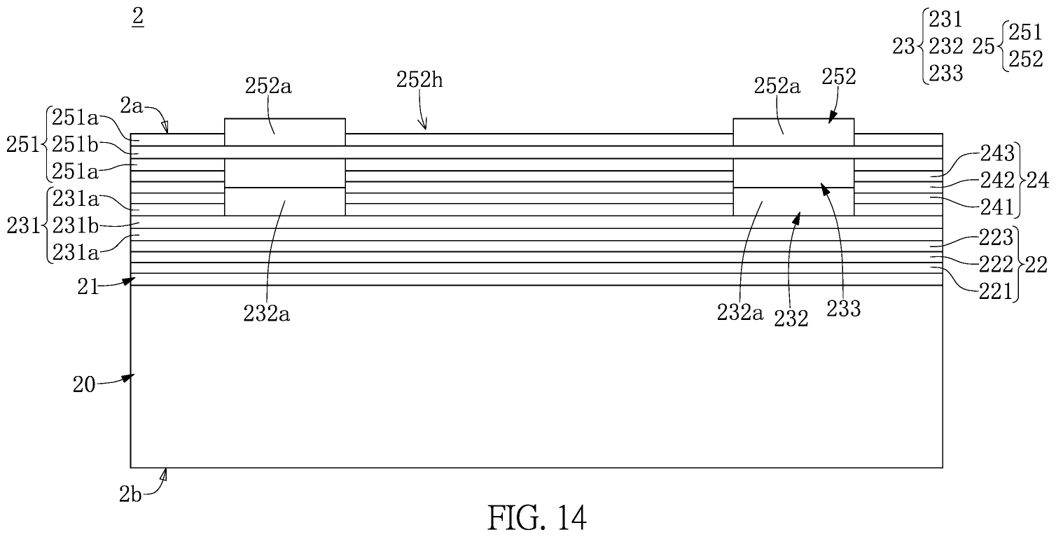

Referring to FIG. 14, the conductive patterned layer 252 is formed on the surface anti-reflective layer 251. The conductive patterned layer 252 includes a plurality of busbar electrode lines 252a and a plurality of finger electrode lines 252b, and each of the finger electrode lines 252b is connected to a corresponding one of the busbar electrode lines 252a. From a top view, the conductive patterned layer 252 is in a mesh shape and has a plurality of openings 252h, as shown in FIG. 4. It is worth mentioning that in the instant embodiment, an orthogonal projection of the conductive patterned layer 252 overlaps with the common conductive patterned layer 232.

In one embodiment, by performing a screen printing process and a sintering process, the aforementioned conductive patterned layer 252 can be fabricated. As shown in FIG. 14, the busbar electrode lines 252a of the conductive patterned layer 252 passes through the outermost transparent conductive oxide layer 251a and is connected to the metal layer 251b. However, the abovementioned example is for exemplary purpose only, and not intended to limit the present disclosure.

### Second Embodiment

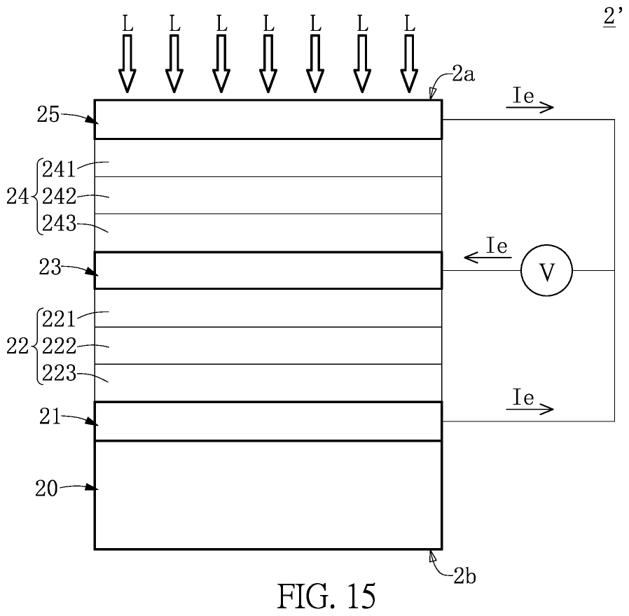

Referring to FIG. 15, FIG. 15 is a schematic view of an electrode coupled double heterojunction solar cell having double active regions for photoelectric effect according to a second embodiment of the present disclosure. The elements of an electrode coupled double heterojunction solar cell (hereinafter referred to as “double heterojunction solar cell”) 2′ in the instant embodiment are denoted by the same reference numerals as those in the first embodiment, and will not be reiterated.

In the instant embodiment, the first P-type semiconductor layer 221 of the first solar cell 22 is connected to the common electrode structure 23, and the first N-type semiconductor layer 223 is connected to the first terminal electrode 21. That is to say, the first N-type semiconductor layer 223, the first intrinsic semiconductor layer 222 and the first P-type semiconductor layer 221 are sequentially stacked on the first terminal electrode 21.

Furthermore, the second P-type semiconductor layer 243 of the second solar cell 24 is connected to the common electrode structure 23, and the second N-type semiconductor layer 241 is connected to a second terminal electrode 25. Accordingly, in the instant embodiment, the second P-type semiconductor layer 243, the second intrinsic semiconductor layer 242 and the second N-type semiconductor layer 241 are sequentially stacked on the common electrode structure 23.

Accordingly, in the instant embodiment, after the sunlight L entering from the light receiving side 2a is absorbed by the first solar cell 22 and the second solar cell 24, photoelectron currents Ie generated in the first solar cell 22 and the second solar cell 24 respectively flow from the first terminal electrode 21 and the second terminal electrode 25 to the common electrode structure 23. Accordingly, the first solar cell 22 and the second solar cell 24 can be electrically connected to each other in a parallel manner through the common electrode structure 23.

### Beneficial Effects of the Embodiments

In conclusion, in the electrode coupled double heterojunction solar cell having double active regions for photoelectric effect and the method of manufacturing the same provided by the present disclosure, by virtue of the common electrode structure 23 being disposed between the first solar cell 22 and the second solar cell 24, so that the first solar cell 22 and the second solar cell 24 can be electrically connected in parallel manner, the photoelectric conversion efficiency of the double heterojunction solar cell 2, 2′ can be improved.

Since the first solar cell 22 and the second solar cell 24 are electrically connected in a parallel manner through the common electrode structure 23, not only can the internal resistance of the double heterojunction solar cell 2 be reduced, but a quantum tunneling effect of electrons at an interface can also be enhanced. In one embodiment, by adjusting the materials of the first solar cell 22 and the second solar cell 24, the first solar cell 22 and the second solar cell 24 can be configured to absorb different light that is contained in sunlight L and has different wavelengths and energies, so as to improve the photoelectric conversion efficiency.

Specifically, the first solar cell 22 and the second solar cell 24 are respectively configured to absorb different light of the sunlight L having different wavelengths and energies, a thermalization loss can be significantly reduced, thereby improving the photoelectric conversion efficiency of the double heterojunction solar cell 2, 2′.

In one embodiment, since the first solar cell 22 is mainly made of polysilicon or microcrystalline silicon, the first solar cell 22 can absorb light contained in sunlight L and having a lower optical energy (or a longer wavelength). Furthermore, since the second solar cell 24 that is closer to the light receiving side 2a is mainly made of amorphous silicon and can be configured to absorb light contained in sunlight L and having a higher optical energy (or a shorter wavelength).

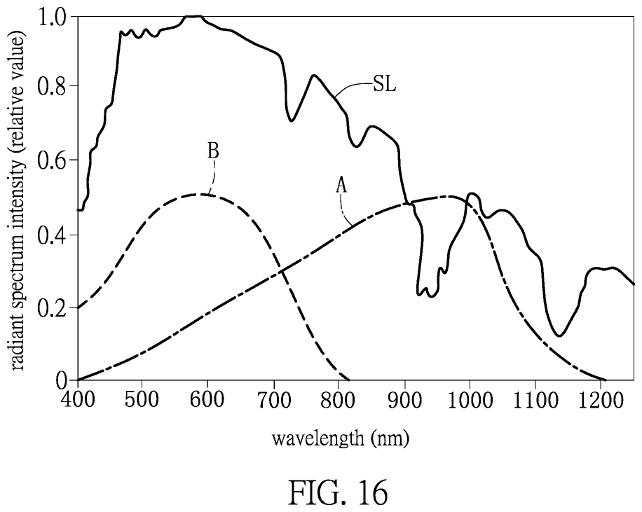

Referring to FIG. 16, a curve SL represents a solar spectrum, a curve A represents optical spectral response of the first solar cell 22 that is mainly made of polysilicon or microcrystalline silicon, and a curve B represents optical spectral response of the second solar cell 24 that is mainly made of amorphous silicon. Compared to the second solar cell 24, the first solar cell 22 has a higher quantum efficiency (or incident photon-electron conversion efficiency) for light having a wavelength falling within a range from 700 nm to 1100 nm (and having a lower optical energy). However, the second solar cell 24 has a higher quantum efficiency (or incident photon-electron conversion efficiency) for light having a wavelength falling within a range from 400 nm to 750 nm (and having a higher optical energy).

That is to say, by providing the first solar cell 22 and the second solar cell 24 respectively having different incident photon-electron conversion efficiencies for different wavelength bands of sunlight, the double heterojunction solar cell 2, 2′ can absorb the light energies of sunlight L in different wavelength bands, thereby significantly improving the photoelectric conversion efficiency. Compared to the conventional silicon based solar cell, each of the double heterojunction solar cells 2, 2′ provided in the embodiments of the present disclosure has a higher photoelectric conversion efficiency. To be more specific, the photoelectric conversion efficiency of the double heterojunction solar cell 2, 2′ is at least 40%, or even reaches 45%. It should be noted that a conventional tandem solar cell is usually fabricated by chemical vapor deposition, such as plasma-assisted chemical vapor deposition, and a fabrication cost thereof is higher. Compared to the conventional tandem solar cell, in the embodiments of the present disclosure, the first solar cell 22, the internal anti-reflective layer 231, the second solar cell 24, and the surface anti-reflective layer 251 can be formed by performing sputtering deposition processes, which can reduce costs of fabrication equipment and process difficulty.

That is to say, modifications made to the structure and manufacturing method of the double heterojunction solar cell 2, 2′ in the present disclosure can be beneficial for mass fabrication of the double heterojunction solar cell 2, 2′ with high photoelectric conversion efficiency.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method of manufacturing an electrode coupled double heterojunction solar cell having double active regions for photoelectric effect comprising:
forming a first solar cell on a first terminal electrode, wherein the first solar cell includes a first PIN heterojunction structure;
forming a common electrode structure on the first solar cell;
forming a second solar cell on the common electrode structure, wherein the second solar cell includes a second PIN heterojunction structure, and the second solar cell is electrically connected to the first solar cell in a parallel manner through the common electrode structure; and
forming a second terminal electrode on the second solar cell.

2. The method according to claim 1, wherein the first solar cell and the second solar cell are both formed by sputtering deposition processes.

3. The nebulizer assembly according to claim 1, wherein the step of forming the first solar cell includes:
forming a first P-type semiconductor layer, a first intrinsic semiconductor layer, and a first N-type semiconductor layer, wherein the first P-type semiconductor layer, the first intrinsic semiconductor layer, and first N-type semiconductor layer are made of microcrystalline silicon or polysilicon; and
performing a rapid thermal annealing process on the first P-type semiconductor layer, the first intrinsic semiconductor layer, and the first N-type semiconductor layer.

4. The method according to claim 1, wherein the first solar cell includes a first P-type semiconductor layer, a first intrinsic semiconductor layer, and a first N-type semiconductor layer, and each one of the first P-type semiconductor layer, the first intrinsic semiconductor layer, and the first N-type semiconductor layer has a thickness ranging from 2 nm to 80 nm.

5. The method according to claim 1, wherein the step of forming the second solar cell further includes:
forming a second N-type semiconductor layer, a second intrinsic semiconductor layer, and a second P-type semiconductor layer on the common electrode structure, wherein the second P-type semiconductor layer and the second intrinsic semiconductor layer are made of amorphous silicon, and the second N-type semiconductor layer are made of amorphous silicon, microcrystalline silicon, or polysilicon.

6. The method according to claim 1, wherein the second solar cell includes a second N-type semiconductor layer, a second intrinsic semiconductor layer, and a second P-type semiconductor layer, and each one of the second N-type semiconductor layer, the second intrinsic semiconductor layer, and the second P-type semiconductor layer has a thickness ranging from 2 nm to 80 nm.

7. The method according to claim 1, wherein the step of forming the common electrode structure includes:
forming an internal anti-reflective layer on the common electrode structure, wherein the internal anti-reflective layer is disposed between the common electrode structure and the first solar cell, and the internal anti-reflective layer includes at least one transparent conductive oxide layer and a metal layer; and
forming a common conductive patterned layer on the internal anti-reflective layer, wherein the common conductive patterned layer includes a plurality of common busbar electrode lines and a plurality of common finger electrode lines, and each of the common finger electrode lines is connected to a corresponding one of the common busbar electrode lines.

8. The method according to claim 7, wherein the step of forming the common electrode structure further includes: forming a patterned insulating layer to cover the common conductive patterned layer.

9. The method according to claim 1, wherein the step of second terminal electrode includes:
forming a surface anti-reflective layer on the second solar cell, wherein the surface anti-reflective layer includes at least one transparent conductive oxide layer and a metal layer; and
forming a conductive patterned layer on the anti-reflective layer, wherein the conductive patterned layer includes a plurality of busbar electrode lines and a plurality of finger electrode lines, and each of the finger electrode lines is connected to a corresponding one of the busbar electrode lines.

10. The method according to claim 1, further comprising: forming a first terminal electrode on a substrate, wherein the substrate is a silicon substrate or a glass substrate.

11. An electrode coupled double heterojunction solar cell having double active regions for photoelectric effect comprising:
a first terminal electrode;
a first solar cell connected to the first terminal electrode, wherein the first solar cell includes a first PIN heterojunction structure;
a second solar cell disposed on the first solar cell, wherein the second solar cell includes a second PIN heterojunction structure;
a common electrode structure disposed between the first solar cell and the second solar cell, so that the first solar cell and the second solar cell are electrically connected to each other in a parallel manner; and
a second terminal electrode disposed on the second solar cell.

12. The electrode coupled double heterojunction solar cell having double active regions for photoelectric effect according to claim 11, wherein the first solar cell includes a first P-type semiconductor layer, a first intrinsic semiconductor layer, and a first N-type semiconductor layer, and the first N-type semiconductor layer and the first P-type semiconductor layer each have a sheet resistivity less than 10⁻² ohm-square.

13. The electrode coupled double heterojunction solar cell having double active regions for photoelectric effect according to claim 11, wherein the second solar cell includes a second N-type semiconductor layer, a second intrinsic semiconductor layer, and a second P-type semiconductor layer, and the second N-type semiconductor layer and the P-type semiconductor layer are respectively and electrically connected to the common electrode structure and the second terminal electrode.

14. The electrode coupled double heterojunction solar cell having double active regions for photoelectric effect according to claim 11, further comprising: a substrate, wherein the first terminal electrode is disposed on the substrate.

15. The electrode coupled double heterojunction solar cell having double active regions for photoelectric effect according to claim 11, further having a light receiving side, wherein the second solar cell is closer to the light receiving side, and the first solar cell is farther away from the light receiving side.

16. The electrode coupled double heterojunction solar cell having double active regions for photoelectric effect according to claim 15, wherein the second solar cell includes a second N-type semiconductor layer, a second intrinsic semiconductor layer, and a second P-type semiconductor layer;
wherein the second intrinsic semiconductor layer and the second P-type semiconductor layer are made of amorphous silicon, and the second N-type semiconductor layer is made of amorphous silicon, microcrystalline silicon, or polycrystalline silicon.

17. The electrode coupled double heterojunction solar cell having double active regions for photoelectric effect according to claim 15, wherein the first solar cell includes a first P-type semiconductor layer, a first intrinsic semiconductor layer, and a first N-type semiconductor layer;
wherein each one of the first P-type semiconductor layer, the first intrinsic semiconductor layer, and the first N-type semiconductor layer is made of microcrystalline silicon or polycrystalline silicon.

18. The electrode coupled double heterojunction solar cell having double active regions for photoelectric effect according to claim 11, wherein the common electrode structure includes:
an internal anti-reflective layer disposed on the first solar cell; and
a common conductive patterned layer disposed on the internal anti-reflective layer, wherein the common electrode structure includes a plurality of common busbar electrode lines and a plurality of common finger electrode lines, and each of the common finger electrode lines is connected to a corresponding one of the common busbar electrode lines.

19. The electrode coupled double heterojunction solar cell having double active regions for photoelectric effect according to claim 18, wherein each of the common busbar electrode lines has a line width ranging from 0.5 mm to 2 mm, and each of the common finger electrode lines has a line width ranging from 5 μm to 10 μm.

20. The electrode coupled double heterojunction solar cell having double active regions for photoelectric effect according to claim 18, wherein the second terminal electrode includes a surface anti-reflective layer and a conductive patterned layer, and an orthogonal projection of the conductive patterned layer overlaps with the common conductive patterned layer.

21. The electrode coupled double heterojunction solar cell having double active regions for photoelectric effect according to claim 11, wherein the first solar cell includes a first P-type semiconductor layer, a first intrinsic semiconductor layer, and a first N-type semiconductor layer, and the second solar cell includes a second N-type semiconductor layer, a second intrinsic semiconductor layer, and a second P-type semiconductor layer;
wherein the first P-type semiconductor layer and the second P-type semiconductor layer are both connected to the common electrode structure.
